(19) United States
(12) Patent Application Publication
(10) Pub. No.: US 2020/0282643 A1
(43) Pub. Date: Sep. 10, 2020

(54) THREE DIMENSIONAL PRINTING DEVICE

(71) Applicant: Young Optics Inc., Hsinchu City (TW)

(72) Inventor: Tsung-Yu Liu, Hsinchu (TW)

(73) Assignee: Young Optics Inc., Hsinchu (TW)

(21) Appl. No.: 16/882,823

(22) Filed: May 26, 2020

Related U.S. Application Data
(63) Continuation of application No. 15/646,250, filed on Jul. 11, 2017.

(51) Int. Cl. B29C 64/205; G03F 7/00; G03F 7/20; B33Y 30/00; B29C 64/214

(52) U.S. Cl. CPC B29C 64/205; G03F 7/0037; B33Y 10/00; B33Y 30/00; B29C 64/214; G03F 7/70416

(57) ABSTRACT

A three dimensional printing device includes a plane putting a photocured material. A pusher mechanism has a contact end above the plane, wherein the contact end is used to contact and remove a portion of the photocured material. The remnant thickness of the removed photocured material is larger than the thickness of a layer of cured pattern.

This is a Continuation of U.S. application Ser. No. 15/646,250, filed Jul. 11, 2017. This continuation application claims the benefit of U.S. patent application Ser. No. 15/646,250, filed Jul. 11, 2017, the contents of which are incorporated herein by reference.

### FIELD OF THE INVENTION

The present invention relates to a printing device, and more particularly to a three dimensional printing device.

### BACKGROUND OF THE INVENTION

In current three dimensional printing technology, a bottom-up Stereo Lithography Apparatus (bottom-up SLA) has been developed. The bottom-up SLA can produce a fine product. A printing platform will be lowered and entirely immersed into a photocured material as the bottom-up SLA performs printing. After that, the photocured material will be illuminated and solidified, and the printing platform will be slowly raised to form a plurality of stacked solid-state patterns on a bottom surface of the printing platform, thereby forming a printed product. However, the above photocured material typically have a predetermined viscosity, that is, most of the typical photocured materials have a low fluidity so that the printing platform immersed into the photocured material will be subjected to uneven buoyancy, thereby causing the printing platform being tilted and not horizontal, and reducing the fineness of printing.

### SUMMARY OF THE INVENTION

An embodiment of the present invention provides a three dimensional printing device including a plane and a pusher mechanism. The plane is capable of putting a photocured material. The pusher mechanism has a contact end above the plane, wherein the contact end is capable of and removing a portion of the photocured material, and wherein a remnant thickness of the removed photocured material is larger than a thickness of a layer of cured pattern. Wherein entire of the pusher mechanism does not contact the plane. Wherein the pusher mechanism is nonrotatable with respect to the plane.

Another embodiment of the present invention provides a three dimensional printing device including a plane, a moveable supplying mechanism and a detector. The plane is capable of putting a photocured material. The supplying mechanism is disposed above the plane, wherein the supplying mechanism is configured to: supply the photocured material to the plane. The detector is disposed above the plane and configured to transmit a signal when a thickness of the photocured material above the plane reaches a predetermined thickness, wherein the predetermined thickness is less than 1 mm.

Another embodiment of the present invention provides a three dimensional printing device including a plane, a projector, a printing platform, a platform driving mechanism and a detector. The plane is capable of putting a photocured material. The projector is configured to emit light capable of curing the photocured material to form a layer of cured pattern. The printing platform has a lower surface capable of attaching the layer of cured pattern. The platform driving mechanism is configured to drive the printing platform to be immersed into the photocured material. The detector is disposed above the plane and configured to transmit a signal when a maximum immersing depth of the lower surface to a top surface of the photocured material reaches a predetermined depth, wherein the predetermined depth is less than 1 mm.

Due to the pusher mechanism or the supplying mechanism used in the invention, so that the thickness of the photocured material above the plane can become thinner (e.g. less than 1 mm). Thus, a volume of the printing platform being immersed into the photocured material can be reduced to dramatically reduce buoyancy, thereby preventing the printing platform from being tilted due to the uneven buoyancy applied thereto, and thereby improving the issue of reducing the fineness of printing due to the uneven printing device.

### BRIEF DESCRIPTION OF THE DRAWINGS

The present invention will become more readily apparent to those ordinarily skilled in the art after reviewing the following detailed description and accompanying drawings, in which:

FIGS. 1A and 1B illustrate schematic diagrams of a three dimensional printing device according to an embodiment of the invention; and

FIG. 2 illustrates a schematic diagram of a three dimensional printing device according to another embodiment of the invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

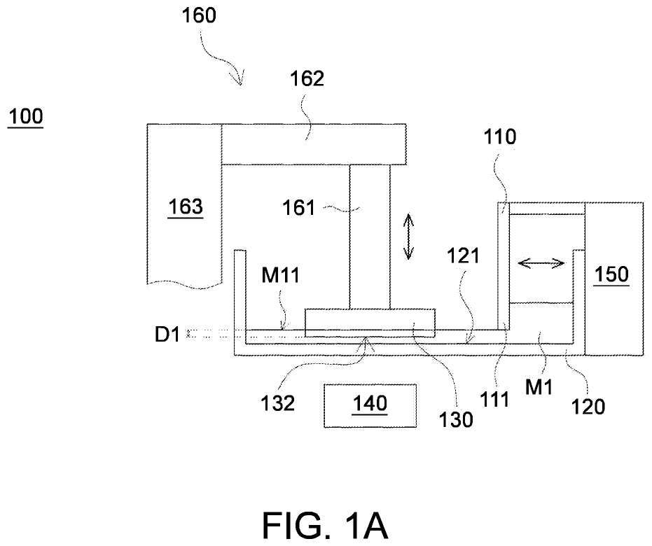

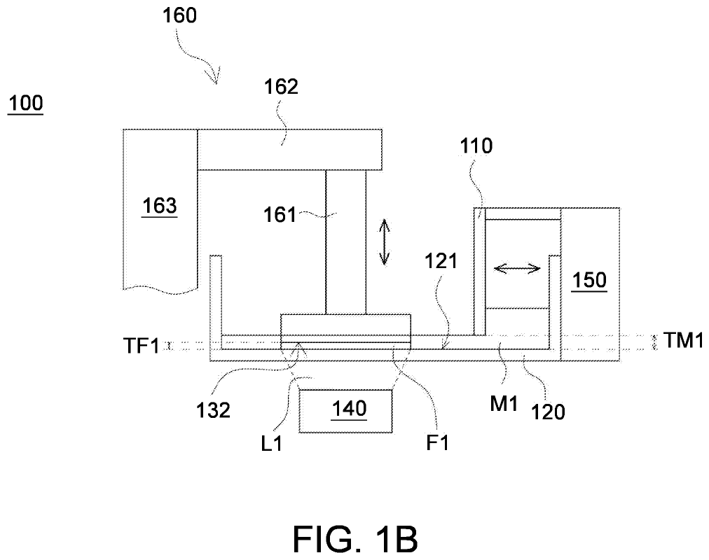

Referring to FIGS. 1A and 1B, the three dimensional printing device 100 includes a pusher mechanism 110, a putting base 120, a printing platform 130, a projector 140, and a driving mechanism 150. The putting base 120 is capable of putting a photocured material M1 and has a plane 121 putting the photocured material M1. The photocured material M1 may be a liquid having a good fluidity or a fluid which is not easily flowable, and the invention is not limited thereto.

The pusher mechanism 110 has a contact end 111 above the plane 121, being configured to contact and remove a portion of the photocured material M1, wherein the pusher mechanism 110 can be, for example, a scraper or a roller. The driving mechanism 150 connects the pusher mechanism 110 and drives the pusher mechanism 110 to move over the plane 121 so that the contact end 111 of the pusher mechanism 110 is able to remove a portion of the photocured material M1. Therefore, a remnant thickness of the removed photocured material M1 over the plane 121 can be reduced to, for example, less than 1 mm, but the present invention is not limited thereto. The driving mechanism 150 may include a power source and a driving assembly connected to the power source, wherein the power source can be, for example, a motor and the driving assembly is connected to the pusher mechanism 110 and may be operated by gears, pulleys, belts or other mechanisms, or combinations of the above mechanisms. Therefore, the driving mechanism 150 can drive the pusher mechanism 110 to move above the plane 121, so that the contact end 111 of the pusher mechanism 110 is able to remove a portion of the photocured material M1.

The printing platform 130 is disposed above the plane 121 and may move upward and downward along a direction toward and away from the plane 121. More specifically, the three dimensional printing device 100 may include a platform driving mechanism 160 which connects the printing platform 130, wherein the platform driving mechanism 160 may include a telescopic lever 161, a cantilever 162, and a motor 163. The motor 163 can be connected and retracted through the driving assembly in the cantilever 162 to drive the printing platform 130 connected to the telescopic lever 161 to move upward and downward. Therefore, the platform driving mechanism 160 can move the printing platform 130 upward and downward toward the direction of toward and away from the plane 121, but the present invention is not limited thereto.

The printing platform 130 has a lower surface 132 used for contacting and being immersed into the photocured material M1, and the projector 140 may emit light L1 toward the plane 121 and the lower surface 132, and the light L1 can penetrate the plane 121 to thereby illuminate the photocured material M1, thereby curing the photocured material M1 so as to form a layer of cured pattern F1 (e.g. as shown in FIG. 1B) above the lower surface 132. Thus, the lower surface 132 of the printing platform 130 can be used to attach the layer of cured pattern F1. In addition, the layer of cured pattern F1 is a basic unit for forming a printed product. That is, the printed product is formed by stacking a plurality of layers of cured patterns F1, and at least two of these stacked layers of cured patterns F1 may be different from each other to form a plurality of final products with different appearances.

When the three dimensional printing device 100 performs printing, the photocured material M1 is first placed above the plane 121. Next, the driving mechanism 150 drives the pusher mechanism 110 to move above the plane 121 to remove a portion of the photocured material M1 so that the photocured material M1 above the plane 121 is thinned, for example, by making a thickness of the photocured material M1 above to the plane 121 being less than 1 mm. Thereafter, the platform driving mechanism 160 drives the printing platform 130 to move in a direction toward the plane 121 so that the lower surface 132 of the printing platform 130 can be immersed into the photocured material M1. As shown in FIG. 1A, a maximum immersion depth D1 of the lower surface 132 to a top surface M11 of the photocured material M1 may be less than 1 mm after the printing platform 130 is immersed into the photocured material M1. Thereafter, the projector 140 emits light L1 which penetrates the plane 121 and illuminates the photocured material M1 so that the photo-cured material M1 illuminated by the light L1 is cured to form the layer of cured pattern F1 above the lower surface 132, wherein a thickness TM1 of the photocured material M1 after being removed by the pusher mechanism 110 is larger than a thickness TF1 of the layer of cured pattern F1, as shown in FIG. 1B. Thereafter, the projector 140 may emit a plurality of different lights L1 to form a plurality of layers of cured patterns F1 with different appearances and being stacked with each other, thereby completing the printed product, and the platform driving mechanism 160 drives the printing platform 130 to move in a direction away from the plane 121, thereby detaching the photocured material M1.

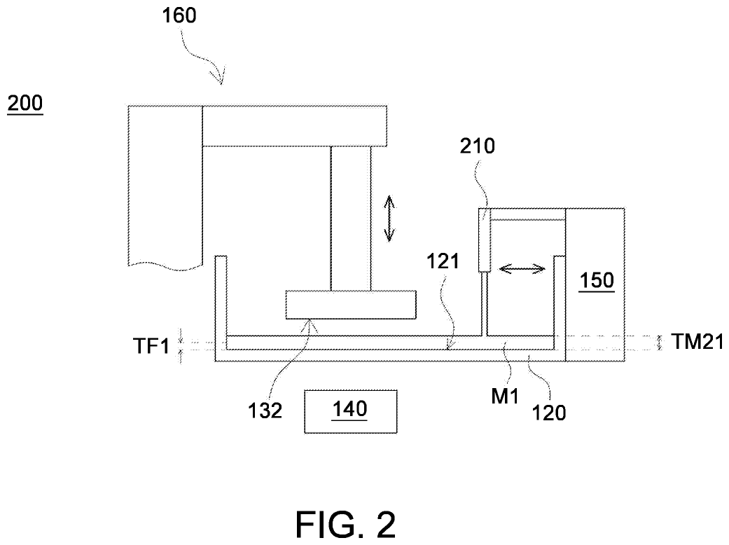

FIG. 2 illustrates a schematic diagram of a three-dimensional printing device according to another embodiment of the present invention. Referring to FIG. 2, it is a schematic view of the three-dimensional printing device 200, and differences between the three-dimensional printing apparatuses 200 and 100 will be described below, and the same features will not be further described.

The three-dimensional printing device 200 of the present embodiment includes a supplying mechanism 210 disposed above the plane 121 but does not include the pusher mechanism 110 described in the foregoing embodiment. The supplying mechanism 210 may be a nozzle and the driving mechanism 150 may be connected to the supply mechanism 210 and may drive the supply mechanism 210 to move above the plane 121. Thus, the three-dimensional printing device 200 can provide the photocured material M1 to the plane 121 with the supplying mechanism 210 to spray a thin layer of photocured material M1 with a thickness TM21 of, for example, less than 1 mm above the plane 121. In addition, in the present embodiment, the supplying mechanism 210 may stop providing the photocured material M1 to the plane 121 prior to the printing platform 130 contacts the photocured material M1 during the printing, but in other embodiments, even if the printing platform 130 is immersed into the photocured material M1, the supplying mechanism 210 can continuously provide the photocured material M1 to the plane 121, and the present invention is not limited thereto.

As disclosed above, the embodiments of present invention makes it possible to make the photocured material above the plane thinner by using a pusher mechanism or a supplying mechanism. In this way, as the printing platform contacts the photocured material for printing, the thin photo-cured material can significantly reduce the buoyancy generated by the printing platform, so that the printing platform will not tilt due to the buoyancy, thereby improving issues caused by uneven buoyancy of the printing platform, and effectively improve the printing fineness.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A three dimensional printing device, comprising:
a plane capable of putting a photocured material; and
a pusher mechanism having a contact end above the plane, wherein the contact end is capable of and removing a portion of the photocured material, and wherein a remnant thickness of the removed photocured material is larger than a thickness of a layer of cured pattern;
wherein entire of the pusher mechanism does not contact the plane;
wherein the pusher mechanism is nonrotatable with respect to the plane.

2. The three dimensional printing device according to claim 1, further comprising a driving mechanism connected to the pusher mechanism.

3. The three dimensional printing device according to claim 2, wherein the driving mechanism further comprises a power source and a driving assembly connected to the power source.

4. The three dimensional printing device according to claim 1, wherein the pusher mechanism is a scraper or a roller.

5. The three dimensional printing device according to claim 1, further comprising:
a projector configured to emit light capable of curing the photocured material; and
a printing platform having a lower surface capable of being immersed into the photocured material.

6. A three dimensional printing device, comprising:
a plane capable of putting a photocured material; and
a moveable supplying mechanism disposed above the plane and configured to
supply the photocured material to the plane; and a detector disposed above the plane and configured to:
transmit a signal when a thickness of the photocured material above the plane reaches a predetermined thickness, wherein the predetermined thickness is less than 1 mm.

7. The three dimensional printing device according to claim 6, further comprising a driving mechanism connected to the moveable supplying mechanism.

8. The three dimensional printing device according to claim 7, wherein the driving mechanism further comprises a power source and a driving assembly connected to the power source.

9. The three dimensional printing device according to claim 8, wherein the driving mechanism is selected from the group of gears, pulleys, belts, and combination of gears, pulleys, and belts.

10. The three dimensional printing device according to claim 6, wherein the moveable supplying mechanism is a nozzle.

11. The three dimensional printing device according to claim 6, further comprising:
a projector configured to emit light capable of curing the photocured material; and
a printing platform having a lower surface capable of being immersed into the photocured material.

12. The three dimensional printing device according to claim 6, wherein the moveable supplying mechanism is configured to stop supplying the photocured material when receiving the signal.

13. A three dimension printing device, comprising:
a plane capable of putting a photocured material;
a projector configured to emit light capable of curing the photocured material to form a layer of cured pattern;
a printing platform having a lower surface capable of attaching the layer of cured pattern; and
a platform driving mechanism configured to:
drive the printing platform to be immersed into the photocured material;
a detector disposed above the plane and configured to:
transmit a signal when a maximum immersing depth of the lower surface to a top surface of the photocured material reaches a predetermined depth, wherein the predetermined depth is less than 1 mm.

14. The three dimensional printing device according to claim 13, further comprising:
a pusher mechanism having a contact end above the plane, wherein the contact end is capable of removing a portion of the photocured material;
wherein entire of the pusher mechanism does not contact the plane, and the pusher mechanism is a scraper or a roller.

15. The three dimensional printing device according to claim 14, further comprising a driving mechanism connected to the pusher mechanism;
wherein the driving mechanism further comprises a power source and a driving assembly connected to the power source.

16. The three dimensional printing device according to claim 13, further comprising:
a moveable supplying mechanism disposed above the plane, wherein the moveable supplying mechanism is capable of supplying the photocured material to the plane.

17. The three dimensional printing device according to claim 16, wherein the moveable supplying mechanism is a nozzle.

18. The three dimensional printing device according to claim 16, further comprising a driving mechanism connected to the moveable supplying mechanism.

19. The three dimensional printing device according to claim 18, wherein the driving mechanism further comprises a power source and a driving assembly connected to the power source.

20. The three dimensional printing device according to claim 13, wherein the platform driving mechanism is configured to stop driving the printing platform when receiving the signal.
